(19) United States
(12) Patent Application Publication
(10) Pub. No.: US 2006/0220757 A1
(43) Pub. Date: Oct. 5, 2006

(54) Semiconductor integrated circuit for communication

(76) Inventors: Kunito Satake, Hitachi (JP); Hirotaka Oosawa, Isesaki (JP); Isao Ikuta, Yokohama (JP); Satoru Yamamoto, Takasaki (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/390,452

(22) Filed: Mar. 28, 2006

(30) Foreign Application Priority Data
Mar. 29, 2005 (JP) 2005-093839

(51) Int. Cl. H03B 5/12

(52) U.S. Cl. 331/179

(57) ABSTRACT

A radio frequency IC includes a PLL circuit and prevents a PLL loop from being easily unlocked upon fluctuation of VCO oscillation frequencies due to a change in temperature. The PLL loop includes a VCO capable of switching oscillation frequency bands, a variable frequency divider, a phase comparison circuit, and a loop filter. A switching switch can apply one of plural predetermined set voltages to the VCO in place of a voltage of the loop filter in an open state in which the loop filter is disconnected from the VCO. The radio frequency IC als has a decision circuit that decides whether the phase of output of the variable frequency divider is ahead of or lags behind that of a reference signal of a predetermined frequency, and an automatic band switching circuit that generates a signal for switching VCO frequency bands, based on output of the decision circuit.

### CROSS-REFERENCE TO RELATED APPLICATION

The present application claims priority from Japanese patent application No 2005-093839 filed on Mar. 29, 2005, the content of which is hereby incorporated by reference into this application.

### BACKGROUND OF THE INVENTION

The present invention relates to technology effectively applied to a PLL (phase locked loop) capable of switching oscillation frequencies of a VCO (voltage controlled oscillator) in stages. For example, the invention relates to technology effectively applied to a PLL circuit that generates an oscillation signal of a predetermined frequency to be synthesized with a receive signal and a transmission signal of radio communication, and a semiconductor integrated circuit for communication including it.

In a radio communication system such as a portable telephone, a semiconductor integrated circuit for radio frequencies (hereinafter referred to a radio frequency IC) that modulates a transmission signal and demodulates a receive signal is used. The radio frequency IC includes a PLL circuit having an oscillator that generates a local oscillation signal of a predetermined frequency to be synthesized with the receive signal and the transmission signal.

Recently, in the field of portable telephones, portable telephones of the WCDMA (Wideband Code Division Multiple Access) system having a wide range of frequency bands are coming into widespread use along with portable telephones of a dual band system capable of handling signals of two frequency bands such as GSM (Global System for Mobile Communication) and DCS (Digital Cellular System), and portable telephones of a multi-band system capable of handling signals of more frequency bands. In accordance with this trend, a PLL circuit to generate local oscillation signals has been required to be able to perform oscillation operations in a wide frequency range. Accordingly, an invention has been proposed which enables selective use of a VCO among plural (e.g., 16) frequency bands to hold a desired oscillation frequency and reduce VCO control sensitivity (Japanese Unexamined Patent Publication No. 2003-152535).

In the preceding applied invention, a system is employed which, before operation is started, measures actual frequencies for all frequency bands of the VCO and stores them in a memory, and when oscillation frequency information is afforded, compares the frequency information and measured frequency values in the memory to decide an optimum frequency band to be used. However, in a PLL circuit of such a system, there is a drawback in that the more the frequency bands of the VCO, the longer it will take to measure frequencies, and a chip size is increased because the capacity of the memory to store measurement results must be increased.

Accordingly, the inventors of the present invention made and filed an invention that includes: a switching switch that can apply predetermined set voltages to a VCO in an open loop; a decision circuit that decides whether the phase of output of the variable frequency divider is ahead of or lags behind that of a reference signal of a predetermined frequency; and an automatic band switching circuit that generates a signal for switching VCO frequency bands, based on the output of the decision circuit, wherein a frequency band to be used is decided by finding an optimum frequency band while switching VCO frequency bands by the binary search method (Japanese Unexamined Patent Publication No. 2005-109618).

### SUMMARY OF THE INVENTION

In a radio communication system of the GSM system, the TDMA (Time Division Multiple Access) system is adopted as a multiplexing system, and transmission/receive data is managed in the unit of a frame comprising eight time slots (hereinafter simply referred to as slots). In the GSM standard, a guard period of 30.46 μs is allowed between a slot and a slot. In the prior invention that decides a frequency band to be used by finding an optimum frequency band while switching VCO frequency bands by the binary search method, a frequency band to be used can be decided within the guard period.

In a radio communication system of the GSM system, even if a frequency fluctuation range of one band is narrow, an automatic band switching operation is performed to decide a frequency band to be used each time a slot begins. Therefore, a change of VCO characteristics due to a change in temperature would be compensated by performing the automatic band switching operation. Hence, there is an advantage in that, even if a PLL circuit of the preceding applied invention that has a narrow frequency fluctuation range of one band is used, it is improbable that a loop will be unlocked because of a change in VCO characteristics due to a change in temperature.

On the other hand, there is a radio communication system of the WCDMA system that uses the spectrum diffusion system as the multiplexing system, and QPSK (Quadrature PSK) as a modulation system. In WCDMA, reception and transmission are successively performed in parallel. Therefore, when a PLL circuit to which the preceding applied invention is applied is used, since band selection is performed only once before transmission/reception is performed, it is possible that VCO characteristics change greatly due to a rise in chip temperatures during transmission/reception, and a PLL loop is unlocked. Accordingly, it was devised that the inclination of oscillation frequency characteristics to control voltage of the VCO was increased to widen a frequency range of one band. However, there is a problem in that increasing the inclination of oscillation frequency characteristics to control voltage of the VCO increases time after the VOC starts oscillation until a PLL loop is locked.

An object of the present invention is to provide a semiconductor integrated circuit for communication (radio frequency IC) that includes a PLL circuit having an oscillator to generate a local oscillation signal of a predetermined frequency to be synthesized with a receive signal and a transmission signal, and prevents a PLL loop from being easily unlocked upon fluctuation of VCO oscillation frequencies due to a change in temperature.

Another object of the present invention is to provide a semiconductor integrated circuit for communication (radio frequency IC) that enables a PLL loop to be locked within a relatively short time after the VCO starts oscillation even when the inclination of oscillation frequency characteristics to control voltage of the VCO is increased.

Still another object of the present invention is to provide a semiconductor integrated circuit for communication (radio frequency IC) suitable to construct a radio communication system in which transmission/reception continues for a relative long time, such as a radio communication system of the WCDMA system.

The aforementioned and other objects of the invention and the novel features thereof will become apparent from the descriptions and the accompanying drawings of this specification.

The summary of the typical inventions of those disclosed in the present application will be briefly explained as follows.

In a PLL loop including a VCO capable of switching oscillation frequency bands, a variable frequency divider, a phase comparison circuit, and a loop filter, there are provided: a switching switch that, when the loop is open, enables application of any one of plural predetermined set voltages to the VCO instead of a voltage of the loop filter; a decision circuit that decides whether the phase of output of the variable frequency divider is ahead of or lags behind that of a reference signal of a predetermined frequency; and an automatic band switching circuit that generates a signal for switching VCO frequency bands, based on the output of the decision circuit, wherein the PLL loop is closed and locked after finding an optimum frequency band while switching VCO frequency bands by the binary search method and finding an optimum applied voltage while switching set voltages applied to the VCO by the binary search method.

According to the above-described means, by increasing the inclination of oscillation frequency characteristics to control voltage of the VCO, a frequency fluctuation range of one band can be widened. Thereby, a PLL loop is prevented from being easily unlocked upon fluctuation of VCO oscillation frequencies due to a change in temperature. Additionally, the PLL loop shifts to a close loop after finding an optimum applied voltage while switching set voltages applied to the VCO by the binary search method. Therefore, even when the inclination of oscillation frequency characteristics to control voltage of the VCO is increased, the PLL loop can be locked in a relatively short time without waiting for it to be naturally locked.

Preferably, during a shift to a close loop after finding an optimum control voltage by the binary search method, switching is made to a higher control voltage before the loop is closed. Since a PLL circuit including a VCO requires less time required to pull in frequencies when a control voltage is pulled in, in a descending order of control voltages, a time required to lock the loop can be reduced.

Effects obtained by typical disclosures of the invention will be described in brief as follows.

According to the present invention, a PLL loop is prevented from being easily unlocked upon fluctuation of VCO oscillation frequencies due to a change in temperature, and additionally, even when the inclination of oscillation frequency characteristics to control voltage of the VCO is increased, the PLL loop can be locked in a relatively short time after the VCO starts oscillation.

### BRIEF DESCRIPTION OF THE DRAWINGS

FIG. 1 is a block diagram showing an embodiment of a PLL circuit according to the present invention;

FIG. 2 is a circuit diagram showing an embodiment of a VCO (voltage controlled oscillation circuit) constituting the PLL circuit of the embodiment of FIG. 1;

FIG. 3 is a characteristic diagram showing a relationship between control voltages Vt and oscillation frequencies fvco in the VCO of FIG. 2;

FIG. 4 is a timing chart showing operation timing of band selection in the PLL circuit of FIG. 1;

FIG. 5A is an illustrative drawing showing an operation region of a VCO when a phase ahead/lag decision circuit decides that the phase of VCO output is ahead, after a set voltage is switched to VN0 during band selection of the PLO circuit of the embodiment of FIG. 1, and FIG. 5B is an illustrative drawing showing an operation region of the VCO when the phase ahead/lag decision circuit decides that the phase of VCO output lags, after a set voltage is switched to VN+1;

FIG. 6A is a timing chart showing reset timing of a variable frequency divider and a fixed frequency divider during band selection of a PLL circuit, studied prior to the present invention, and FIG. 6B is a timing chart showing reset timing of the variable frequency divider and the fixed frequency divider during band selection of the PLO circuit of FIG. 1; and

FIG. 7 is a block diagram showing the configuration of a semiconductor integrated circuit for communication (radio frequency IC) to which a PLL circuit according to the present invention is applied, and a radio communication system employing it.

### DETAILED DESCRIPTION OF THE PREFERRED EMBODIMENTS

The following describes embodiments of the present invention with reference to the accompanied drawings.

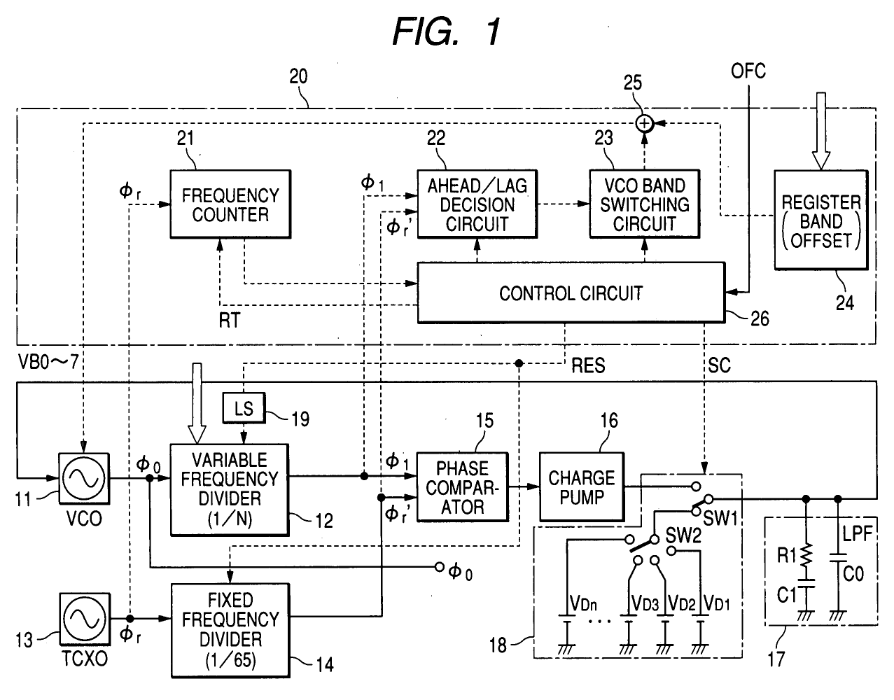

FIG. 1 shows an embodiment of a PLL circuit according to the present invention having a function for automatically selecting a band used by a VCO, based on frequency information externally set.

The PLL circuit of this embodiment includes: a voltage controlled oscillation circuit (VCO) 11; a variable frequency divider 12 that frequency-divides an oscillation signal φ0 of the VCO 11 to 1/N; a fixed frequency divider 14 that frequency-divides an oscillation signal φr from a reference oscillation circuit 13 that generates a reference oscillation signal φr such as 16 MHz; a phase comparator 15 that detects a phase difference between signals φ1 and φr′ frequency-divided by the variable frequency divider 12 and the fixed frequency divider 14; a charge pump 16 that generates a charging current or discharge current corresponding to the detected phase difference; and a loop filter 17 that generates voltage corresponding to output current of the charge pump 16. A voltage smoothed by the loop filter 17 is fed back to the VCO 11 as an oscillation control voltage Vt.

Although there is no particular limitation, in this embodiment, the VCO 11 is constructed to have 32 frequency bands (hereinafter referred to as bands) The fixed frequency divider 14 has a frequency division ratio of 1/40, and frequency-divides a reference oscillation signal φref of 16 MHz to generate a signal of 400 kHz. The loop filter 17 is constituted as a secondary filter comprising a capacitor C0, and a resistor R1 and a capacitor C1 that are provided in parallel with the capacitor C0.

The PLL circuit of this embodiment is provided with a switching switch circuit 18 between the charge pump 16 and the loop filter 17. The switching switch circuit 18 comprises a switching switch SW1 for supplying a set voltage in place of a current of the charge pump to the loop filter 17, and a switch SW2 for selectively applying any one of plural set voltages VD1, VD2, . . . , VDn divided almost equally between voltages Vmin and Vmax in a control range of the VCO 11 to one terminal of the switching switch SW1.

Furthermore, an automatic band switching circuit 20 is provided that controls the switching switch circuit 18, and compares output of the variable frequency divider 12 and output of the fixed frequency divider 14 to generate a signal for switching bands used by the VCO 11. Although the phase comparator 15 and the charge pump 16 are shown as distinct circuits in this embodiment, the charge pump is not required in cases where an output stage of the phase comparator 15 operates as a current source of the charge pump, depending on circuit types.

The automatic band switching circuit 20 includes: a frequency counter 21 as a timer that counts the reference oscillation signal φr from the reference oscillation circuit 13 to conduct timing; a decision circuit 22 that compares output of φ1 of the variable frequency divider 12 and output φr′ of the fixed frequency divider 14 to decide whether the phase of output of φ1 of the variable frequency divider 12 is ahead of or lags behind the phase of output φr′ of the fixed frequency divider 14; and a band switching circuit 23 that generates band switching control signals VB0 to VB4 for switching bands of the VCO 11 according to a decision result of the decision circuit 22. Moreover, the automatic band switching circuit 20 includes: a register 24 that holds offset set from the outside; an adding circuit 25 as an offset imparting circuit that adds the offset set in the register 24 to the band switching control signals VB0 to VB4 outputted from the band switching circuit 23 and supplies the result to the VCO 11; and a control circuit 26 that actuates the switching switch 18, frequency counter 21, decision circuit 22, band switching circuit 23, register 24, and adding circuit 25 in a predetermined order to decide a band to be used.

The control circuit 26 has a function for generating a reset signal RT for resetting the frequency counter 21, and a reset signal RES for resetting the variable frequency divider 12 and the fixed frequency divider 14. Moreover, a level shift circuit 19 for converting the level of the reset signal RES is provided between the control circuit 26 and the variable frequency divider 12.

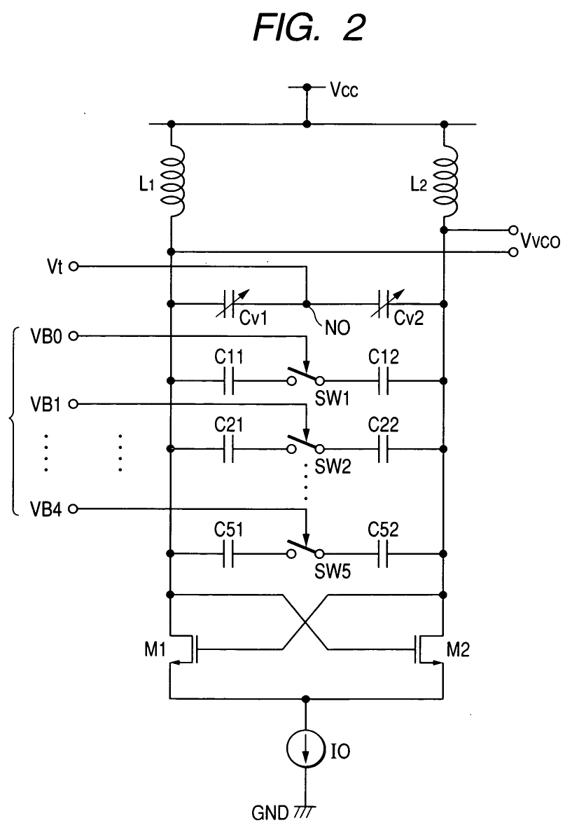

FIG. 2 shows an example of the construction of the voltage controlled oscillation circuit (VCO) 11 used in this embodiment.

The VCO of this embodiment, which is an LC resonance type oscillation circuit, includes a pair of N-channel MOS transistors M1 and M2 the sources of which are connected in common and the gates and drains of which are mutually cross-coupled; a constant-current source IO connected between the common source of the transistors M1 and M2, and a ground point GND; inductors L1 and L2 connected respectively between drains of the transistors M1 and M2, and a power supply voltage terminal Vcc; variable capacitors Cv1 and Cv2 comprising varactor diodes and the like connected in series between drain terminals of the transistors M1 and M2; capacitor C11-switch SW1-capacitor C12 connected in series between drain terminals of the transistors M1 and M2; and C21-SW2-C22, C31-SW3-C32, . . . and C51-SW5-C52 connected in parallel to them.

In the VCO of this embodiment, a control voltage Vt from the loop filter 17 of FIG. 1 is applied to a connection node N0 of the variable capacitive elements Cv1 and Cv2 to successively change oscillation frequencies, while band switching control signals VB0 to VB4 from the automatic band switching circuit 20 are supplied to the switches SW1 to SW5 so that oscillation frequencies are changed in stages (32 stages) by combinations of the respective high and low levels of the VB0 to VB4.

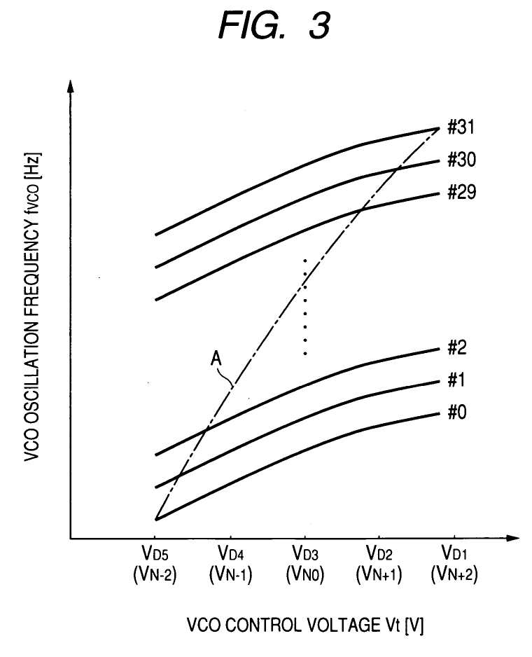

The capacitors C11 and C12 have the same capacitance value, and C21 and C22, C31 and C32, C41 and C42, and C51 and C52 also have the same capacitance value, respectively. However, the capacitance values of the capacitors C11, C21, C31, C41, and C51 are set to have weights of the m-th power of two (m is 0, 1, 2, . . . , 4), combined capacitance values C are changed in 32 stages according to combinations of the band switching control signals VB0 to VB4, and the VCO 11 is made to operate in any one of frequency characteristics of 32 bands #0 to #31 shown in FIG. 3.

If a frequency range to be covered by the VCO is to be widened only by changing capacitance values of the varactor diodes by control voltages Vt, Vt-fvco characteristic becomes too steep as shown by the alternate long and short dash line A in FIG. 3, and the sensibility of the VCO, that is, a ratio between frequency change quantity and control voltage change quantity (Δf/ΔVt) becomes large, weakening resistance to noise. In short, slight noise on the control voltages Vt would cause a great change in oscillation frequencies of the VCO.

To solve this problem, in the VCO of this embodiment, plural capacitive elements constituting an LC resonance circuit are provided in parallel, and the connected capacitive elements are switched to 32 stages by the band switching control signals VB0 to VB4 to change the values of C. By this construction, as shown by the solid lines of FIG. 3, oscillation control based on the 32 Vt-fvco characteristic lines can be performed, and any one of the characteristics is selected for operation according to a band to be used.

Like the prior invention (Japanese Unexamined Patent Publication No. 2005-109618) described previously, the number of switchable bands can be increased to a greater number such as 256 to increase resistance to noise. In such a case, however, a change in VCO oscillation frequencies due to temperature change could cause a PLL loop to be unlocked or require an excessively long time for band selection. Accordingly, in this embodiment, the number of switchable bands of VCO is set to 32.

Though there is no particular limitation, in the LC resonance type oscillation circuit of this embodiment, the capacitors C11 to C52 have a sandwich structure consisting of a metallic film, an insulating film, and a metallic film formed on a semiconductor board. By properly setting an area ratio of electrodes constituting the capacitors C11 to C52, a desired capacitance ratio (the m-th power of two) can be obtained. Hereinafter, the capacitors C11 to C52 will be referred to as band switching capacitors. As the capacitors C11 to C52, capacitors between gate electrodes of MOS transistors and the board may be used. Inductors L1 and L2 may be formed as on-chip elements comprising an aluminum layer formed on the semiconductor board, but may also be used as external elements.

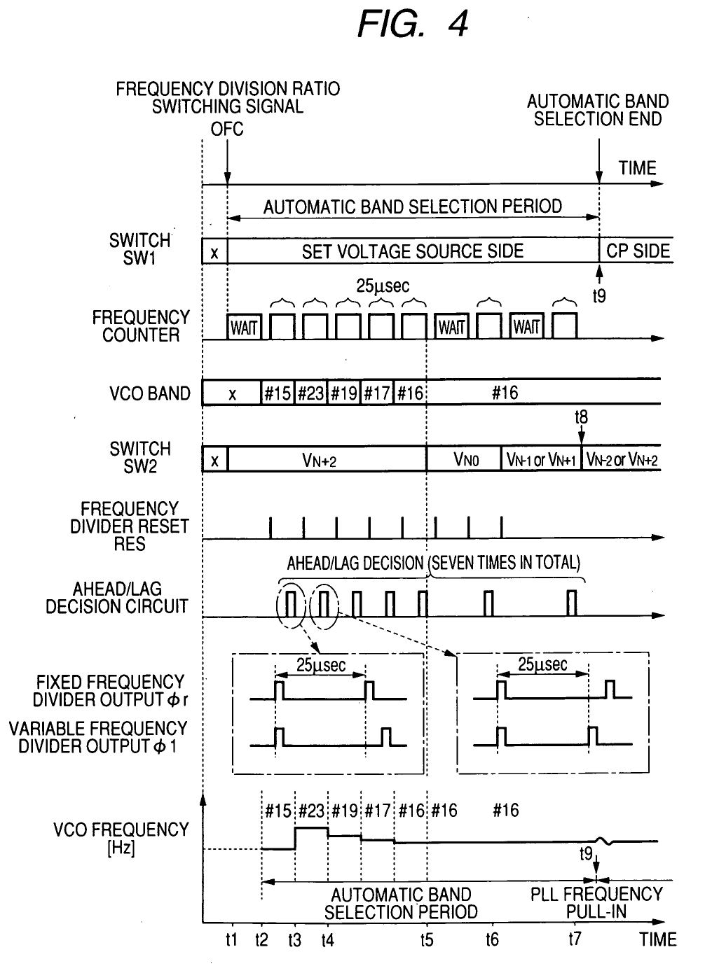

With reference to a timing chart of FIG. 4, the following describes a procedure for the decision of a band to be selected and selection of a set voltage by the automatic band switching circuit 20 in the PLL circuit of FIG. 1.

When a signal OFC for switching of oscillation frequency is supplied to the control circuit 26 from the outside, the control circuit 26 outputs a switch switching signal SC for switching the switching switch SW1 of the switching switch circuit 18 on the PLL loop to the set voltage VD1-VDn side, and a signal RT for resetting the frequency counter 21, while a frequency division ratio “N” of the variable frequency divider 12 supplied from the outside is set in the variable frequency divider 12 (timing t1). The frequency division ratio corresponds to oscillation frequency information.

The first time that the switching switch circuit 18 is switched to the set voltage VD1-VDn side, the switch SW2 is set to select, for example, the highest set voltage VD1 of these voltages, the set voltage is supplied to the VCO 11 as a control voltage Vt, and the VCO starts oscillation at a frequency corresponding to the set voltage. Specifically, for example, when five voltages VN−2, VN−1, VN0, VN+1, and VN+2 (VN−2<VN−1<VN0<VN+1<VN+2) are provided as set voltages, the highest voltage VN+2 is selected.

After inputting a reset signal RT, the frequency counter 21 starts a counting operation by an accurate reference oscillation signal φr from the crystal-oscillation circuit 13. After 5 is (microseconds) elapses, a signal indicating the elapsed time is sent to the control circuit 26. The time of 5 μs is set as a time required to stabilize an oscillation frequency of the VCO 11 with a voltage of the loop filter 17 and a set voltage supplied to the loop filter 17. When 5 μs has elapsed, the control circuit 26 signals the VCO band switching circuit 23 to send band switching control signals VB0 to VB4 to the VCO 11. Thereby, a capacitive element selectively connected in the VCO 11 is decided, and a band to be selected is specified (timing t2). The first specified band is a central band #15 of the 32 bands #0 to #31.

After waiting for a time (e.g., 0.5 μs) necessary for band switching of the VCO 11, the control circuit 26 sends a reset signal RES of pulse shape to the variable frequency divider 12 and the fixed frequency divider 14. The variable frequency divider 12 and the fixed frequency divider 14 are counter circuits that are reset to “0” by the reset signal RES and start counting after the reset is cleared. When previously set frequency division ratios “N” and “40” have been counted, they output pulses φ1 and φr′, respectively.

Since the fixed frequency divider 14 operates according to an exact reference oscillation signal φr (16 MHz) from the crystal-oscillation circuit 13, the frequency of the output pulse φr′ is 400 kHz and its cycle is 2.5 μs. These output pulses φ1 and φr′ are supplied to the phase ahead/lag decision circuit 22. The ahead/lag decision circuit 22 decides whether the rise of the output pulse φ1 of the variable frequency divider 12 is ahead of or lags behind the rise of the output pulse φr′ of the fixed frequency divider 14.

When the phase ahead/lag decision circuit 22 decides that the output pulse φ1 of the variable frequency divider 12 lags, it signals the VCO band switching circuit 23 to send band switching control signals VB0 to VB4 specifying a band of a higher frequency than that of the current band to the VCO 11 (timing t3). On the other hand, on deciding that the output pulse φ1 of the variable frequency divider 12 is ahead, the phase ahead/lag decision circuit 22 signals the VCO band switching circuit 23 to send band switching control signals VB0 to VB4 specifying a band of a lower frequency than that of the current band to the VCO 11. The band specified by the second band switching control signals VB0 to VB4 is #23 being the middle between #15 and #31 when φ1 lags, and #7 being the middle between #15 and #0 when φ1 is ahead.

When a band switching command is issued, the control circuit 26 waits for a time (e.g., 0.5 μs) required for band switching by the VCO 11, and then sends again the reset signal RES to the variable frequency divider 12 and the fixed frequency divider 14. The variable frequency divider 12 and the fixed frequency divider 14 restart counting after being temporarily reset to “0.” When previously set frequency division ratios “N” and “40” have been counted, they output pulses φ1 and φr′, respectively. The ahead/lag decision circuit 22 decides whether the rise of the output pulse φ1 of the variable frequency divider 12 is ahead of or lags behind the rise of the output pulse φr′ of the fixed frequency divider 14.

When the phase ahead/lag decision circuit 22 decides that the output pulse φ1 of the variable frequency divider 12 lags, it signals the VCO band switching circuit 23 to send band switching control signals VB0 to VB4 specifying a band of a higher frequency than that of the current band to the VCO 11 (timing t4). On the other hand, on deciding that the output pulse φ1 of the variable frequency divider 12 is ahead, the phase ahead/lag decision circuit 22 signals the VCO band switching circuit 23 to send band switching control signals VB0 to VB4 specifying a band of a lower frequency than that of the current band to the VCO 11. The band specified by the third band switching control signals VB0 to VB4 is one of #19 being the middle between #15 and #23, #27 being the middle between #23 and #31, #11 being the middle between #15 and #7, and #3 being the middle between #7 and #0.

By repeating the above-described operation five times, a band suitable for a specified oscillation frequency (frequency corresponding to the set frequency division ratio N) is selected from the 32 bands (timing t5). In the fifth decision, the band selected in the fourth decision or a band just above it (or a band just below it) is selected. In the automatic band switching circuit 20 of this embodiment, an offset is added to the band selected in the fifth decision to decide a band finally selected. The offset is added to compensate for a decision error due to a difference between actual reset operations of the variable frequency divider 12 and the fixed frequency divider 14 by the reset signal RES. The addition of offset, which is not mandatory, will be described in detail later.

In the automatic band switching circuit, after the above-described operation terminates, the set voltages VD1 to VDn are switched to find a set voltage close to an optimum control voltage and pulled in a PLL loop. A method of finding the set voltage is described below.

As described previously, when band selection is started, the highest voltage VN+2 is first selected as a set voltage by the switch SW2. This is because a band selection operation beginning with the highest voltage requires less time to stabilize VCO output than a band selection operation beginning with the lowest voltage. However, a middle voltage VN0 may be first applied as a set voltage. In this embodiment, decisions are made five times with the set time VN+2 applied, and after a band (e.g., #16) decided in the fifth decision is selected, the highest selected set voltage VN+2 is switched to a middle voltage VN0 (timing t5). After waiting for a time required until a voltage of the loop filter 17 and an oscillation frequency of the VCO 11 are stabilized, the ahead/lag decision circuit 22 decides whether the rise of the output pulse φ1 of the variable frequency divider 12 is ahead of or lags behind the rise of the output pulse φr′ of the fixed frequency divider 14 (timing t6).

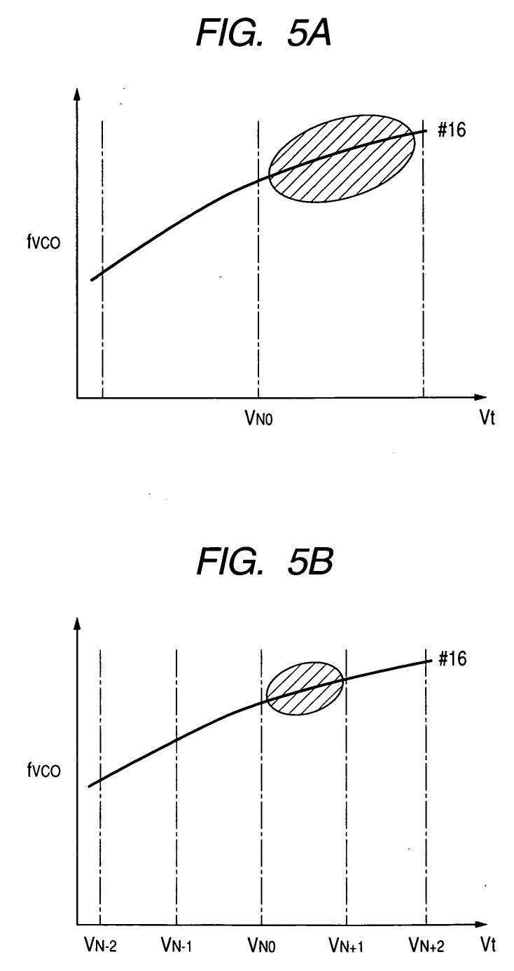

When it is decided that the rise of φ1 is ahead of the rise of φr′, it will be appreciated that oscillation frequencies of the VCO are in a region of higher voltages than the set voltage VN0 (to the right of the VN0) as hatched in FIG. 5A, and the VCO operates in the region. On the other hand, when it is decided that the rise of φ1 lags behind the rise of φr′, it will be appreciated that oscillation frequencies of the VCO are in a region of lower voltages than the set voltage VN0 (to the left of the VN0), and the VCO operates in the region.

Accordingly, when the rise of φ1 is ahead of the rise of φr′, the switch SW2 is switched to switch a set voltage applied to the VCO 11 from VN0 to VN+1, and when φ1 lags behind φr′, the switch SW2 is switched to switch a set voltage applied to the VCO 11 from VN0 to VN−1 (timing t7). After waiting that the loop filter 17 is stabilized with VN+1 or VN−1, the ahead/lag decision circuit 22 again decides whether the rise of φ1 is ahead of the rise of φr′.

For example, when it is decided that the rise of φ1 lags behind the rise of φr′ with a set voltage set to VN+1, it will be appreciated that oscillation frequencies of the VCO are in a region that is to the right of the VN0 and to the left of VN+1 as hatched in FIG. 5B, and the VCO operates in the region. When it is decided that the rise of φ1 is ahead of the rise of φr′, it will be appreciated that oscillation frequencies of the VCO are in a region to the right of the set voltage VN+1, and the VCO operates in the region. In this embodiment, the processing terminates after the above-described two decisions because five set voltages are provided. However, when there are more set voltages, the above-described operations are repeated to decide a set voltage to be selected by the binary search method.

When it is decided in the final decision that the rise of φ1 lags behind the rise of φr′, a set voltage VN+1 having been selected by the switch SW2 at that time is selected, and when it is decided that the rise of φ1 is ahead of the rise of φr′, the switch SW2 is switched to switch a set voltage applied to the VCO 11 from VN+1 to VN+2 (timing t8). In short, a higher set voltage in a region in which the VCO operates is selected. This is because a pull-in operation beginning with a higher voltage requires less lock time than a pull-in operation beginning with a lower voltage.

After that, after waiting that the loop filter 17 is stabilized with a selected set voltage, the PLL circuit switches the switch SW1 from the set voltage side to the loop filter 17 side, and immediately proceeds to a normal frequency pull-in operation of the PLL loop (timing t9). By the above-described control, the PLL loop can be locked in a short time.

The following describes the offset addition described previously. A difference between reset operations of the variable frequency divider 12 and the fixed frequency divider 14 occurs for two reasons. One reason is that the reset signal RES outputted from the control circuit 26 is supplied to the variable frequency divider 12 through the level shift circuit 19 that performs conversion from CMOS level to ECL level, while it is supplied to the fixed frequency divider 14 without level conversion.

For the following reason, the reset signal RES is supplied to the variable frequency divider 12 with level conversion, while it is supplied to the fixed frequency divider 14 without level conversion. Since the frequencies of oscillation signals of the VCO 11 frequency-divided by the variable frequency divider 12 have the order of GHz (gigahertz), and are much higher than the frequency 16 MHz of crystal oscillation signals frequency-divided by the fixed frequency divider 14, the variable frequency divider 12 is constituted by ECL circuits comprising bipolar transistors capable of higher speed operation than MOSFET, while the fixed frequency divider 14 is constituted by CMOS circuits to reduce power consumption.

Another reason for a difference occurring between reset operations of the variable frequency divider 12 and the fixed frequency divider 14 lies in a delay time difference occurring due to a supply path of the reset signal RES longer in a path from the control circuit 26 to the variable frequency divider 12 than in a path from the control circuit 26 to the fixed frequency divider 14. The reason that a difference occurs between supply paths of the reset signal RES is generally that any of frequency dividers is closer to a control circuit in terms of layout. However, in this embodiment, since the frequency counter 21 and the fixed frequency divider 14 use in common or share part of circuits, the fixed frequency divider 14 is necessarily positioned closer to the control circuit 26 than is the variable frequency divider 12, causing the difference. A delay time difference due to such a difference between supply paths is not described here because it is described in the prior invention (Japanese Unexamined Patent Publication No. 2005-109618) and is not a main point of the present invention.

The following describes the need to decide a band finally selected by adding an offset to compensate for a decision error due to a difference between reset operations of the variable frequency divider 12 and the fixed frequency divider 14.

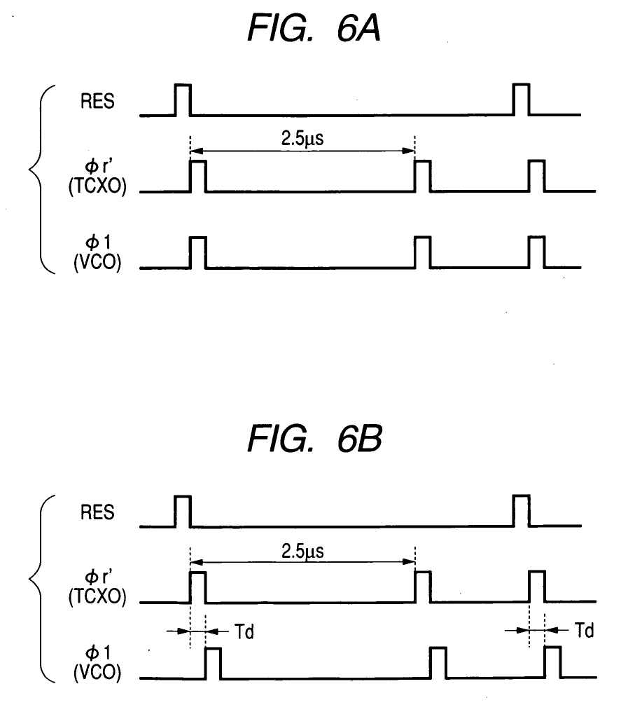

In the automatic band switching circuit of an embodiment in which the phase ahead/lag decision circuit 22 decides whether the rise of the output pulse φ1 of the variable frequency divider 12 is ahead of or lags behind the rise of the output pulse φr′ of the fixed frequency divider 14, when there is no difference between reset operations of the variable frequency divider 12 and the fixed frequency divider 14, as shown in FIG. 6A, since the rise of the output pulse φr′ of the fixed frequency divider 14 coincides with the rise of the output pulse φ1 of the variable frequency divider 12 during a reset by the reset signal RES, a decision about whether a phase is ahead or lags that is made 2.5 μs later can be correctly performed.

On the other hand, when there is a difference between reset operations of the variable frequency divider 12 and the fixed frequency divider 14, and the variable frequency divider 12 is reset later, as shown in FIG. 6B, the rise of the output pulse φ1 of the variable frequency divider 12 already lags behind the rise of the output pulse φr′ of the fixed frequency divider 14 during a reset, a decision about whether a phase is ahead or lags cannot be correctly made. Specifically, when the variable frequency divider 12 is reset later, even if the cycle of the output pulse φ1 of the variable frequency divider 12 is the same as the cycle of the output pulse φr′ of the fixed frequency divider 14 and it is time to decide a band to be selected, it would be decided that the rise of φ1 lags, and the band switching circuit 23 would be commanded to select a band of a shorter cycle (higher frequency).

Accordingly, in the automatic band switching circuit of this embodiment, an offset is added to a signal (code) specifying a band selected based on a result of making a decision with a delay due to the reset signal RES included, whereby a band lower in frequency by an offset corresponding to a delay Td than a band decided by a decision result of the ahead/lag decision circuit 22 is selected as a final band to be used. As for an offset value set from the outside, after previously deciding an offset corresponding to an average delay Td measured by inspection, an offset to be actually set may be decided taking variations of individual products into account.

To compensate for a transfer delay Td of the reset signal RES to the variable frequency divider 12, a delay circuit affording a delay corresponding to the Td may be provided on a supply path of the reset signal RES from the control circuit 26 to the variable frequency divider 12. However, in a system providing such a delay circuit, correct decisions may not be made because of variations of delay time of the delay circuit due to manufacturing variations. On the other hand, in this embodiment, since an offset is afforded from the outside and a band to be selected is shifted by the offset, by changing the offset value afforded from the outside, an optimum band can be selected even if transfer delays Td of the reset signal RES vary due to manufacturing variations.

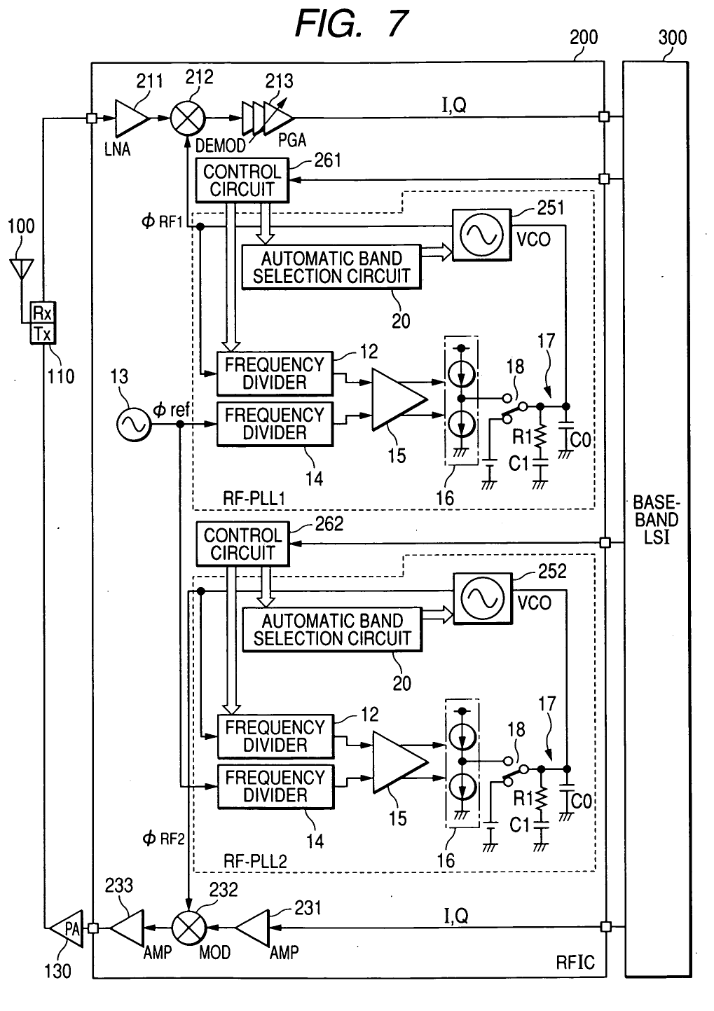

With reference to FIG. 7, the following describes an embodiment of a semiconductor integrated circuit for communication (radio frequency IC) to which the PLL circuit of the above-described embodiment is applied, and a radio communication device such as a portable telephone employing it. This embodiment is applied to a radio frequency IC of a so-called direct conversion system. Circuits and elements in FIG. 7 that are identical to those in FIG. 1 are identified by the same reference numerals, and duplicate descriptions of them will be omitted. Although this embodiment is suitably used to construct portable telephones of the WCDMA system, it can also be used to construct portable telephones of the GSM system.

A radio communication system shown in FIG. 7 includes: an antenna 100 that transmits and receives signal waves; a duplexer 110 (demultiplexer) that separates transmission signals and receive signals; a radio frequency power amplifier 130 (power amplifier) that amplifies transmission signals; a radio frequency IC 200 that modulates receive signals and modulates transmission signals; and a baseband circuit 300 that performs baseband processing such as the conversion of transmission data into I and Q signals, and extraction of receive data from demodulated I and Q signals, and controls the radio frequency IC 200. In this embodiment, the radio frequency IC 200 and the baseband circuit 300 are formed as semiconductor integrated circuits on distinct semiconductor chips, respectively. In the case of the GSM system, a transmission/reception switching switch is used instead of the duplexer 110, and a band-pass filter comprising a SAW filter and the like that removes unnecessary waves from a receive signal is provided between the switch and a receive signal input terminal of the radio frequency IC 200.

The radio frequency IC 200 of this embodiment broadly includes a reception system circuit, a transmission system circuit, and a control system circuit that comprises circuits common to a transmission/reception system such as a control circuit and a clock system circuit.

The reception system circuit includes: a low noise amplifier 211 that amplifies receive signals; a mixer 212 that performs demodulation and down-convert by synthesizing an oscillation signal φRF1 generated by a radio frequency oscillation circuit (RFPLL) 251, and a receive signal amplified by the low noise amplifier 211; and a high-gain amplifying unit (PGA) 213 that amplifies demodulated I and Q signals, and outputs them to the baseband circuit 300.

The transmission system circuit includes: an amplifier 231 that amplifies I and Q signals supplied from the baseband circuit 300; a mixer 232 that performs modulation and up-convert by synthesizing amplified I and Q signals, and an oscillation signal φRF2 generated by the RFVCO 252; and an amplifier 233 that amplifies a modulated signal.

In this embodiment, the PLL circuit shown in FIG. 1 is used as an RF-PLL1 that generates a radio frequency signal φRF1 synthesized with a receive signal in the mixer 212, and an RF-PLL2 that generates a radio frequency signal φRF2 synthesized with a transmission signal in the mixer 232. The reference oscillation circuit 13 that generates a reference clock φref required in the RF-PLL1 and the RF-PLL2 is provided as a common circuit. The RF-PLL1 and the RF-PLL2 are respectively provided with control circuits 261 and 262 that generate signals for controlling the RF-PLL1, the RF-PLL2, and the above-described reception system circuit and the transmission system circuit, based on signals from the baseband circuit 300.

The control circuits 261 and 262 are provided with a control register and a data register. The offset value and oscillation frequency (frequency division ratio “N”) are set in these registers, based on signals from the baseband IC 300, and the values set in the registers are supplied to the register 24 for setting offset within the automatic band switching circuit 20 and the variable frequency divider 12 of the RF-PLL. Based on commands (command codes and the like) from the baseband IC 300, an oscillation frequency switching control signal OFC is supplied to the automatic band switching circuit 20 from the control circuits 261 and 262. The control circuits may be provided as circuits common to the RF-PLL1, the RF-PLL2, and the above-described reception system circuit and the transmission system circuit.

Transmission and reception are performed in parallel in the WCDMA system, while, in the GSM system, transmission and reception are performed with a time shift between them while switching is made between transmission slots and reception slots. Therefore, when the present invention is applied to a radio frequency IC constituting a portable telephone of the GSM system, the RF-PLL circuits that generate radio frequency signals φRF1 and φRF2 supplied to the mixer 212 that performs down-converts and the mixer 232 that performs up-convert in FIG. 7 can be constructed to be shared.

Although the invention made by the inventors has been described in detail based on embodiments, the present invention is not limited to the embodiments. For example, although the VCO 11 is switched to any one of 32 bands, the number of bands may be 16, 64, or the like.

In the embodiments described previously, in the final decision during a band selection operation, when it is decided that the VCO operates in a region of voltages higher than an applied set voltage, a set voltage higher than the set voltage at that time is selected. However, in the final decision, the VCO may immediately use the applied set voltage, and when it is decided in the final decision that the VCO operates in a region of voltages lower than an applied set voltage, a set voltage lower than the set voltage at that time may be selected. Such control is effective particularly when a VCO whose oscillation frequency increases due to a rise in temperatures is used.

Furthermore, for example, a VCO whose oscillation frequency decreases due to a rise in temperatures is used, and when it is decided during band selection that the VCO is operating in a region close to the smallest voltage in a frequency fluctuation range of the band to be selected, a band directly below it may be selected. Conversely, a VCO whose oscillation frequency increases due to a rise in temperatures is used, and when it is decided during band selection that the VCO is operating in a region close to the highest voltage in a frequency fluctuation range of the band to be selected, a band directly above it may be selected.

The invention made by the inventors has been primarily described with respect to the case where it is applied to a radio frequency IC used in a radio communication system such as portable telephones. The present invention, without being limited to the above, can apply to a radio frequency IC for wireless LAN, and other radio frequency ICs having a PLL circuit that generates a radio frequency signal to be synthesized with a receive signal and a transmission signal for frequency conversion and modulation/demodulation.

What is claimed is:

1. A semiconductor integrated circuit for communication comprising:
a loop that includes: an oscillation circuit constructed to be able to oscillate in plural frequency bands; a variable frequency divider that frequency-divides an output signal of the oscillation circuit at a specified frequency division ratio; a fixed frequency divider that frequency-divides a reference signal having a predetermined frequency at a predetermined frequency division ratio; a phase comparison circuit that compares the phase of an output signal of the variable frequency divider and the phase of an output signal of the fixed frequency divider to detect a phase difference; a loop filter that generates a control voltage corresponding to the output of the phase comparison circuit, and controls oscillation frequencies of the variable oscillation circuit by a control voltage generated by the loop filter;
a switching means that can supply a voltage of a predetermined level to the loop filter in place of the output of the phase comparison circuit when the loop is open; and
a band switching circuit that, in a state of supplying a control voltage of the predetermined level to the oscillation circuit by supplying the voltage of the predetermined level to the loop filter by the switching means, compares the phase of an output signal of the variable frequency divider and the phase of an output signal of the fixed frequency divider to select an oscillation frequency band of the oscillation circuit,
wherein, after applying a control voltage of a first predetermined level to the oscillation circuit by the switching means, and selecting a frequency band by the band switching circuit, the semiconductor integrated circuit for communication applies a control voltage of a predetermined level different from the first predetermined level, and decides in which region on a line of control voltage to oscillation frequency characteristics the oscillation circuit is operating, based on a comparison result of the phase comparison circuit.

2. The semiconductor integrated circuit for communication according to claim 1, in a state of applying a control voltage of the first predetermined level or a control voltage of another predetermined level to the oscillation circuit, closing the loop to start a frequency locking operation.

3. The semiconductor integrated circuit for communication according to claim 2, wherein the semiconductor integrated circuit for communication provides three or more of control voltages of the predetermined levels, switches these control voltages to decide in which region on a line of control voltage to oscillation frequency characteristics the oscillation circuit is operating, and in a state of applying one of the three or more of control voltages of the predetermined levels to the oscillation circuit, closing the loop to start a frequency locking operation.

4. The semiconductor integrated circuit for communication according to claim 3,
wherein the number of regions in which the oscillation circuit can operate is the n-th power (n is a positive integer) of two, and the semiconductor integrated circuit for communication decides a region in which the oscillation circuit operates, by a binary search method while switching the control voltages.

5. The semiconductor integrated circuit for communication according to claim 1,
wherein the control voltage to oscillation frequency characteristics of the oscillation circuit has positive characteristics that when a control voltage is higher, a frequency becomes higher, and when the oscillation circuit is operating in a region corresponding to a control voltage higher than the control voltages of the predetermined levels on a line of control voltage to oscillation frequency characteristics, in a state of applying a control voltage of another predetermined level higher than the control voltages of the predetermined levels to the oscillation circuit, closing the loop to start a frequency locking operation, while when the oscillation circuit is operating in a region corresponding to a control voltage lower than the control voltages of the predetermined levels on a line of control voltage to oscillation frequency characteristics, in a state of applying the control voltages of the predetermined levels to the oscillation circuit, closing the loop to start a frequency locking operation.

6. The semiconductor integrated circuit for communication according to claim 1,
wherein the band switching circuit decides a final frequency band to be selected, by the binary search method through repeated executions of comparison between the phase of an output signal of the variable frequency divider and the phase of an output signal of the fixed frequency divider, and changes of an oscillation frequency band to be selected based on the comparison result.

7. The semiconductor integrated circuit for communication according to claim 1, wherein the semiconductor integrated circuit for communication closes the loop to start a frequency locking operation in a state of keeping the frequency band or switching it to an adjacent frequency band according to the decision result and the temperature characteristics of oscillation frequencies of the oscillation circuit, and applying a control voltage of another predetermined level to the oscillation circuit.

8. The semiconductor integrated circuit for communication according to claim 7,
wherein the control voltage to oscillation frequency characteristics of the oscillation circuit has positive characteristics that when a control voltage is higher, an oscillation frequency becomes higher,
wherein the temperature characteristics of oscillation frequencies of the oscillation circuit have negative characteristics that when a temperature is higher, an oscillation frequency becomes lower, and when it is decided that the oscillation circuit is operating in a region corresponding to a control voltage lower than the control voltages of the predetermined levels on a line of control voltage to oscillation frequency characteristics, the semiconductor integrated circuit for communication switches an oscillation frequency band to an adjacent oscillation frequency band of a lower oscillation frequency, and
wherein the temperature characteristics of oscillation frequencies of the oscillation circuit have positive characteristics that when a temperature is higher, an oscillation frequency becomes higher, and when it is decided that the oscillation circuit is operating in a region corresponding to a control voltage higher than the control voltages of the predetermined levels on a line of control voltage to oscillation frequency characteristics, the semiconductor integrated circuit for communication switches an oscillation frequency band to an adjacent oscillation frequency band of a higher oscillation frequency.

9. The semiconductor integrated circuit for communication according to claim 1, wherein the semiconductor integrated circuit for communication processes receive signals of the WCMDA system using a first local oscillation signal of a first frequency, and processes transmission signals of the WCMDA system using a second local oscillation signal of a second frequency,
wherein the first local oscillation signal and the second local oscillation signal are respectively generated by distinct oscillation circuits.

10. The semiconductor integrated circuit for communication according to claim 1, which processes receive signals and transmission signals of the GSM system using local oscillation signals of predetermined frequencies,
wherein the local oscillation signals are generated by the oscillation circuit.

11. A semiconductor integrated circuit for communication, comprising:
a loop that includes: an oscillation circuit constructed to be able to oscillate in one continuous frequency band; a variable frequency divider that frequency-divides an output signal of the oscillation circuit at a specified frequency division ratio; a fixed frequency divider that frequency-divides a reference signal having a predetermined frequency at a predetermined frequency division ratio; a phase comparison circuit that compares the phase of an output signal of the variable frequency divider and the phase of an output signal of the fixed frequency divider to detect a phase difference; and a loop filter that generates a voltage corresponding to the output of the phase comparison circuit, and controls oscillation frequencies of the variable oscillation circuit by a voltage generated by the loop filter; and
a switching means that can supply a voltage of a predetermined level to the loop filter in place of the output of the phase comparison circuit when the loop is open,
wherein, in a state of supplying a control voltage of the predetermined level to the oscillation circuit by supplying the voltage of the predetermined level to the loop filter by the switching means, the semiconductor integrated circuit for communication compares the phase of an output signal of the variable frequency divider and the phase of an output signal of the fixed frequency divider, decides in which region on a line of voltage to frequency characteristics the oscillation circuit is operating, by a binary search method while switching the control voltages, and in a state of applying a control voltage of a predetermined level corresponding to the decision result to the oscillation circuit, closes the loop to start a frequency locking operation.
